(19) United States
(12) Patent Application Publication
(10) Pub. No.: US 2023/0046413 A1
(43) Pub. Date: Feb. 16, 2023

(54) SEMICONDUCTOR PACKAGE ASSEMBLY

(71) Applicant: MEDIATEK INC., Hsinchu City (TW)

(72) Inventors: Tai-Yu CHEN, Hsinchu City (TW); Chin-Lai CHEN, Hsinchu City (TW); Hsiao-Yun CHEN, Hsinchu City (TW); Wen-Sung HSU, Hsinchu City (TW); Haw-Kuen SU, Hsinchu City (TW); Duen-Yi HO, Hsinchu City (TW); Bo-Jiun YANG, Hsinchu City (TW); Ta-Jen YU, Hsinchu City (TW); Bo-Hao MA, Hsinchu City (TW)

(21) Appl. No.: 17/812,786

(22) Filed: Jul. 15, 2022

Related U.S. Application Data
(60) Provisional application No. 63/232,704, filed on Aug. 13, 2021.

(51) Int. Cl. H01L 25/10; H01L 25/18

(52) U.S. Cl. CPC H01L 25/105; H01L 25/18; H01L 2225/1058; H01L 24/48

(57) ABSTRACT

A semiconductor assembly package is provided. The semiconductor package assembly includes a system-on-chip (SOC) package, a memory package and a heat spreader. The SOC package includes a logic die and a first substrate. The logic die has pads on it. The first substrate is electrically connected to the logic die by the pads. The memory package includes a second substrate and a memory die. The second substrate has a top surface and a bottom surface. The memory die is mounted on the top surface of the second substrate and is electrically connected to the second substrate using bonding wires. The heat spreader is disposed between the SOC package and the memory package, wherein the heat spreader is in contact with a back surface of the logic die away from the pads.

### CROSS REFERENCE TO RELATED APPLICATIONS

This application claims the benefit of U.S. Provisional Application No. 63/232,704, filed Aug. 13, 2021, the entirety of which is incorporated by reference herein.

### BACKGROUND OF THE INVENTION

### Field of the Invention

The present invention relates to a semiconductor package assembly, and, in particular, to a semiconductor package assembly having the improved heat dissipation capability and reduced package height.

### Description of the Related Art

Package-on-package (PoP) package assembly is an integrated circuit packaging method to combine vertically discrete system-on-chip (SOC) and memory packages. Two or more packages are installed atop each other, i.e., stacked, with a standard interface to route signals between them. This allows higher component density in devices, such as mobile phones, personal digital assistants (PDA), and digital cameras.

High band package on package (HBPOP) is usually apply as a package candidate for high end smart phone SOC and has advantages of high bandwidth and short path of signal transmission. However, HBPOP still faces challenges of thermal dissipation and package height shrinkage.

Thus, a novel semiconductor package assembly is desirable.

### BRIEF SUMMARY OF THE INVENTION

An embodiment of the present invention provides a semiconductor package assembly. The semiconductor package assembly comprises a system-on-chip (SOC) package, a memory package and a heat spreader. The SOC package comprises a logic die and a first substrate. The logic die has pads on it. The first substrate is electrically connected to the logic die by the pads. The memory package comprises a second substrate and a memory die. The second substrate has a top surface and a bottom surface. The memory die is mounted on the top surface of the second substrate and is electrically connected to the second substrate using bonding wires. The heat spreader is disposed between the SOC package and the memory package, wherein the heat spreader is in contact with a back surface of the logic die away from the pads.

An embodiment of the present invention provides a semiconductor package assembly. The semiconductor package assembly comprises a system-on-chip (SOC) package, a memory package and a heat spreader. The SOC package comprises a logic die and a first substrate. A back surface of the logic die is exposed from a top surface of the SOC package. The memory package comprises a second substrate and a memory die. The second substrate has a top surface and a bottom surface. The memory die is mounted on the top surface of the second substrate and is electrically connected to the second substrate using bonding wires. The heat spreader overlaps the bottom surface of the second substrate and is in contact with the back surface of the logic die.

In addition, an embodiment of the present invention provides a semiconductor package assembly. The semiconductor package assembly comprises a system-on-chip (SOC) package, a memory package and a heat spreader. The SOC package comprises a logic die and a first substrate. The first substrate is electrically connected to the logic die. The memory package comprises a second substrate and a memory die. The second substrate has a top surface and a bottom surface. The memory die is mounted on the top surface of the second substrate and is electrically connected to the second substrate using bonding wires. The heat spreader is disposed between the SOC package and the memory package, being in contact with the logic die.

### BRIEF DESCRIPTION OF THE DRAWINGS

The present invention can be more fully understood by reading the subsequent detailed description and examples with references made to the accompanying drawings, wherein:

FIG. 1 is a cross-sectional of a semiconductor package assembly in accordance with some embodiments of the disclosure;

FIG. 2A is a top view showing the arrangements of a heat spreader and a memory package of the semiconductor package assembly shown in FIG. 1 in accordance with some embodiments of the disclosure;

FIG. 2B is a side view showing the arrangements of a heat spreader and a memory package of the semiconductor package assembly shown in FIG. 1 in accordance with some embodiments of the disclosure;

FIG. 2C is a bottom view showing the arrangements of a heat spreader and a memory package of the semiconductor package assembly shown in FIG. 1 in accordance with some embodiments of the disclosure;

FIG. 3 is a cross-sectional of a semiconductor package assembly in accordance with some embodiments of the disclosure;

FIG. 4A is a top view showing the arrangements of a heat spreader and a memory package of the semiconductor package assembly shown in FIG. 3 in accordance with some embodiments of the disclosure;

FIG. 4B is a side view showing the arrangements of a heat spreader and a memory package of the semiconductor package assembly shown in FIG. 3 in accordance with some embodiments of the disclosure;

FIG. 4C is a bottom view showing the arrangements of a heat spreader and the memory package of the semiconductor package assembly shown in FIG. 3 in accordance with some embodiments of the disclosure;

FIG. 5 is a cross-sectional of a semiconductor package assembly in accordance with some embodiments of the disclosure;

FIG. 6A is a top view showing the arrangements of a heat spreader and a system-on-chip (SOC) package of the semiconductor package assembly shown in FIG. 5 in accordance with some embodiments of the disclosure;

FIG. 6B is a side view showing the arrangements of a heat spreader and a system-on-chip (SOC) package of the semiconductor package assembly shown in FIG. 5 in accordance with some embodiments of the disclosure; and

FIG. 7 is a cross-sectional of a semiconductor package assembly in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention

Embodiments provide a semiconductor package assembly. The semiconductor package assembly provides a system-on-chip (SOC) package and a memory package stacked on it and integrated as a three-dimensional (3D) high band package in package (HBPIP) semiconductor package assembly. The semiconductor package assembly uses an underfill filled the gap between the upper memory package and the lower SOC package to improve the thermal performance (e.g., the thermal resistance from the SOC package to the memory package). In addition, the SOC package is fabricated without an interposer provided for the electrical connections between the SOC package and the memory package. Therefore, the height of the semiconductor package assembly can be further reduced. Furthermore, the semiconductor package assembly further comprises a heat spreader between the bottom surface of the memory package and the top surface of the SOC package to directly dissipate the heat from the SOC package. Therefore, the heat dissipation capability of the semiconductor package assembly can be further improved.

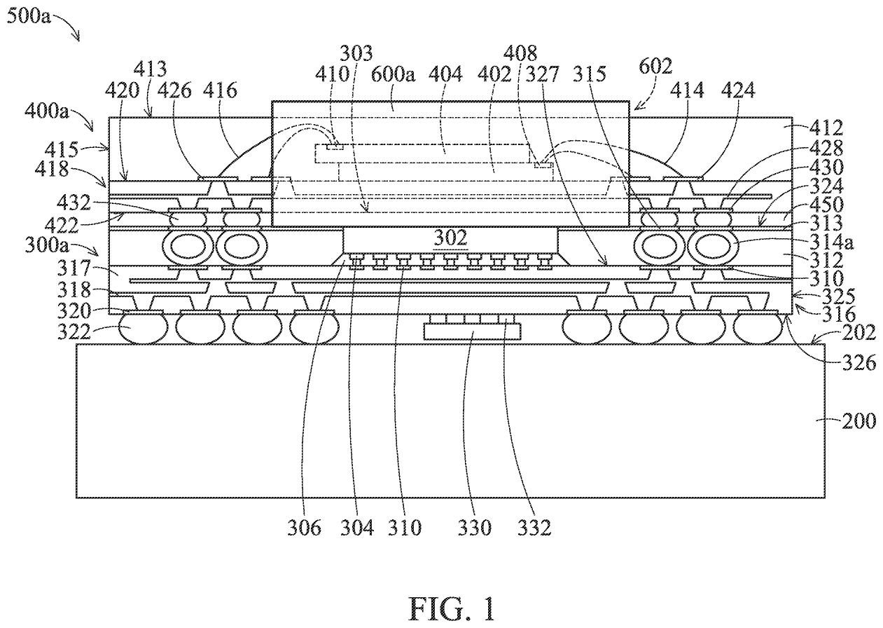

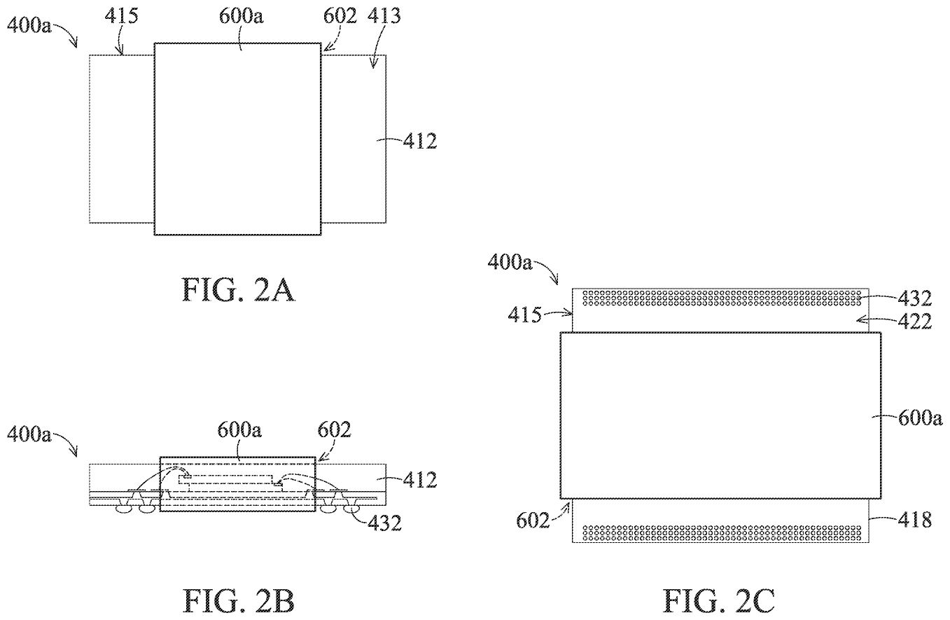

FIG. 1 is a cross-sectional of a semiconductor package assembly 500a in accordance with some embodiments of the disclosure. FIG. 2A is a top view showing the arrangements of a heat spreader 600a and a memory package 400a of the semiconductor package assembly 500a shown in FIG. 1 in accordance with some embodiments of the disclosure. FIG. 2B is a side view showing the arrangements of the heat spreader 600a and the memory package 400a of the semiconductor package assembly 500a shown in FIG. 1 in accordance with some embodiments of the disclosure. FIG. 2C is a bottom view showing the arrangements of the heat spreader 600a and the memory package 400a of the semiconductor package assembly 500a shown in FIG. 1 in accordance with some embodiments of the disclosure. In some embodiments, the semiconductor package assembly 500a is a three-dimensional (3D) package-in-package (PIP) semiconductor package assembly. The semiconductor package assembly 500a may include at least two vertically stacked wafer-level semiconductor packages mounted on a base 200. As shown in FIG. 1, in some embodiments, the semiconductor package assembly 500a includes a system-on-chip (SOC) package 300a, a memory package 400a vertically stacked on the SOC package 300a, and the heat spreader 600a wrapping around the memory package 400a.

As shown in FIG. 1, the base 200, for example a printed circuit board (PCB), may be formed of polypropylene (PP). It should also be noted that the base 200 can be a single layer or a multilayer structure. A plurality of pads (not shown) and/or conductive traces (not shown) is disposed on a die-attach surface 202 of the base 200. In one embodiment, the conductive traces may comprise signal trace segments or ground trace segments, which are used for the input/output (I/O) connections of the SOC package 300a and the memory package 400a. Also, the SOC package 300a is mounted directly on the conductive traces. In some other embodiments, the pads are disposed on the die-attach surface 202, connected to different terminals of the conductive traces. The pads are used for the SOC package 300a that is mounted directly on them.

As shown in FIG. 1, the SOC package 300a is mounted on the die-attach surface 202 of the base 200 by a bonding process. The SOC package 300a is mounted on the base 200 using the conductive structures 322. The SOC package 300a is a three-dimensional (3D) semiconductor package including a logic die 302 and a substrate 316. For example, the logic die 302 may include a central processing unit (CPU), a graphic processing unit (GPU), a dynamic random access memory (DRAM) controller or any combination thereof.

As shown in FIG. 1, the logic die 302 is disposed on a surface 327 of the substrate 316 away from the conductive structures 322. The logic die 302 has a back surface 303 and a front surface 306. The logic die 302 is fabricated by a flip-chip technology. The back surface 303 of the logic die 302 is aligned with a top surface 324 of the SOC package 300a. In other words, the back surface 303 of the logic die 302 is exposed from the top surface 324 of the SOC package 300a. Pads 304 of the logic die 302 are disposed on the front surface 306 to be electrically connected to the circuitry (not shown) of the logic die 302. In some embodiments, the pads 304 belong to the uppermost metal layer of the interconnection structure (not shown) of the logic die 302. The pads 304 of the logic die 302 are in contact with the corresponding pads 310 close to the surface 327 of the substrate 316. In some embodiments, an underfill (not shown) is introduced into the gap between the logic die 302 and the substrate 316.

As shown in FIG. 1, the substrate 316 is provided for the logic die 302 to be disposed upon. The substrate 316 is electrically connected to the logic die 302 via the pads 304 of the logic die 302. In some embodiments, the substrate 316 includes a redistribution layer (RDL) structure having one or more conductive traces 318 disposed in one or more intermetal dielectric (IMD) layers 317. The conductive traces 318 are electrically connected to corresponding contact pads 320. The contact pads 320 are exposed to openings of the solder mask layer (not shown). In addition, the conductive structures 322 are disposed on a surface 326 of substrate 316 away from the logic die 302 and in contact with the corresponding the contact pads 320. The surface 326 of substrate 316 may serve as the bottom surface of the SOC package 300a. However, it should be noted that the number of conductive traces 318, the number of IMD layers 317 and the number of contact pads 320 shown in FIG. 1 is only an example and is not a limitation to the present invention.

As shown in FIG. 1, the SOC package 300a further includes a molding compound 312 disposed on the surface 327 of the substrate 316 and surrounding the logic die 302. The molding compound 312 is in contact with the substrate 316 and the logic die 302. The back surface 303 of the logic die 302 is exposed from the molding compound 312. In some embodiments, the molded compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the logic die 302, and then may be cured using a UV or thermally curing process. The molding compound 312 may be cured with a mold.

As shown in FIG. 1, the SOC package 300a further includes a solder mask layer 313 and pads 315 disposed covering a surface (i.e., an interface between the solder mask layer 313 and the molding compound 312) of the molding compound 312 opposite the substrate 316. In addition, the pads 315 and the solder mask layer 313 are disposed close to the top surface 324 of the SOC package 300a. The pads 315 and the back surface 303 of the logic die 302 are exposed to openings of the solder mask layer 313. In some embodiments, the pads 315 provided electrical connections between the SOC package 300a and the memory package 400a.

As shown in FIG. 1, the SOC package 300a further includes conductive structures 314a passing through the molding compound 312 and electrically connected to the substrate 316 and the pads 315 of the SOC package 300a and the memory package 400a. The conductive structures 314a are disposed between the memory package 400a and the substrate 316 of the SOC package 300a. The conductive structures 314a and the logic die 302 may be disposed side-by-side and on the surface 327 of the substrate 316 opposite the conductive structures 322. In addition, the conductive structures 314a may be disposed as an array along parallel edges (not shown) of the SOC package 300a, which are close to a pair of parallel side surfaces 325 of the SOC package 300a. Therefore, the logic die 302 is disposed between the conductive structures 314a. In some embodiments, the conductive structures 314a may comprise a conductive ball structure such as a copper ball, a conductive bump structure such as a copper bump or a solder bump structure, or a conductive pillar structure such as a copper pillar structure.

As shown in FIG. 1, the SOC package 300a further includes an electronic component 330 mounted on the surface 326 of the substrate 316 opposite the logic die 302. In some embodiments, the electronic component 330 has pads 332 on it and is electrically connected to the conductive traces 318 of the substrate 316. In some embodiments, the electronic component 330 is arranged between the conductive structures 322. The electronic component 330 can be free from being covered by a molding compound. In some embodiments, the electronic component 330 comprises integrated passive device (IPD) including a capacitor, an inductor, a resistor, or a combination thereof. In some embodiments, the electronic component 330 comprises DRAM dies.

As shown in FIG. 1, the memory package 400a is stacked on the SOC package 300a by a bonding process. In some embodiments, the memory package 400a comprises a dynamic random access memory (DRAM) package or another applicable memory package. In some embodiments, the memory package 400a includes a substrate 418 and at least one memory die, for example, two memory dies 402 and 404 that are stacked on the substrate 418. In some embodiments, the memory die 402 comprises a dynamic random access memory (DRAM) die or another applicable memory die. The substrate 418 has a top surface 420 and a bottom surface 422. For example, the top surface 420 may serve as a die-attach surface 420, and the bottom surface 422 may serve as a bump-attach surface 422 opposite the die-attach surface 420. In this embodiment, as shown in FIG. 1, there are two memory dies 402 and 404 mounted on the top surface (die-attach surface) 420 of the substrate 418. The memory die 404 is stacked on the memory die 402 using a paste (not shown), and the memory die 402 is mounted on die-attach surface 420 of the substrate 418 by a paste (not shown). The memory dies 402 and 404 may be electrically connected to the substrate 418 using bonding wires 414 and 416. However, the number of stacked memory dies is not limited to the disclosed embodiment. Alternatively, the memory dies 402 and 404 as shown in FIG. 1 can be arranged side by side. Therefore, the memory dies 402 and 404 are mounted on the top surface (die-attach surface) 420 of the substrate 418 by paste.

As shown in FIG. 1, the substrate 418 may comprise a circuitry 428 and metal pads 424 and 426 and 430. The metal pads 424 and 426 are disposed on the top of the circuitry 428 close to the top surface (die-attach surface) 420. The metal pads 430 are disposed on the bottom of the circuitry 428 close to the bottom surface (bump-attach surface) 422 of the substrate 418. The circuitry 428 of the memory package 400a is interconnected to the conductive traces 318 of the substrate 316 via the conductive structures 432 disposed on the bottom surface (bump-attach surface) 422 of the substrate 418. In some embodiments, the memory package 400a is electrically coupled to the conductive traces 318 of the substrate 316 by the conductive structures 314 passing through the molding compound 312 between the memory package 400a and the substrate 316 of the SOC package 300a. In addition, the conductive structures 432 are electrically connected to the conductive structures 314a via the pads 315 of the SOC package 300a. In some embodiments, the conductive structures 432 may comprise a conductive bump structure such as a copper bump or a solder bump structure, a conductive pillar structure, or a conductive paste structure.

In some embodiments, as shown in FIG. 1, the memory package 400a further includes a molding material 412 covering the top surface 420 of the substrate 418, encapsulating the memory dies 402 and 404 and the bonding wires 414 and 416. The molding materials 312 and 412 may comprise the same or similar materials and fabrication processes.

As shown in FIG. 1, the semiconductor package assembly 500a further comprises an underfill 450 that fills the gap between the SOC package 300a and the memory package 400a, so that the memory package 400a can be stacked on the SOC package 300a without there being a gap between them. The conductive structures 432 of the memory package 400a are surrounded by the underfill 450. In some embodiments, as shown in FIG. 1, the underfill 450 is in contact with the conductive structures 432 and the bottom surface 422 of the substrate 418 of the memory package 400a (which also serves as the bottom surface of the memory package 400a) the top surface 324 of the SOC package 300a. Therefore, the molding compound 312 of the SOC package 300a is separated from the substrate 418 of the memory package 400a by the underfill 450. In some embodiments, the underfill 450 includes a capillary underfill (CUF), a molded underfill (MUF), or a combination thereof.

As shown in FIG. 1, the heat spreader 600a is disposed between the SOC package 300a and the memory package 400a. In some embodiments, the heat spreader 600a is adjacent to and in contact with the underfill 450 and the logic die 302. In addition, the heat spreader 600a is in contact with the back surface 303 of the logic die 302 away from the pads 304. Furthermore, the heat spreader 600a fully covers the back surface 303 of the logic die 302. As shown in FIGS. 1 and 2A-2C, the heat spreader 600a is wrapped around the memory package 400a and covers the entire memory dies 402 and 404. As shown in FIGS. 1 and 2A-2C, the heat spreader 600a covers portions of a top surface 413 and side surfaces 415 of the memory package 400a and partially overlaps the bottom surface 422 of the substrate 418 of the memory package 400a. The heat spreader 600a is formed without covering a portion of the bottom surface 422 of the substrate 418 close to and/or covered by the conductive structures 432, as shown in FIGS. 1 and 2A-2C. As shown in FIGS. 1, 2B and 2C, the conductive structures 314a of the SOC package 300a and the conductive structures 432 of the memory package 400a are separated from the heat spreader 600a. Therefore, a short between the conductive structures 432 and/or the conductive structures 314a and the heat spreader 600a can be avoided. In some embodiments, the heat spreader 600a comprises a conductive material, such as metals comprising copper, gold, silver, or other applicable metals. For example, the heat spreader 600a may comprise copper foils. In some embodiments, the semiconductor package assembly 500a further comprises an adhesive 602 to adhere the heat spreader 600a (e.g., a copper foil) to the memory package 400a. The adhesive 602 is disposed between the heat spreader 600a and the memory package 400a. In some embodiments, the adhesive 602 comprises conductive silver paste, acrylic adhesive, conductive ceramic adhesive, or other applicable adhesives.

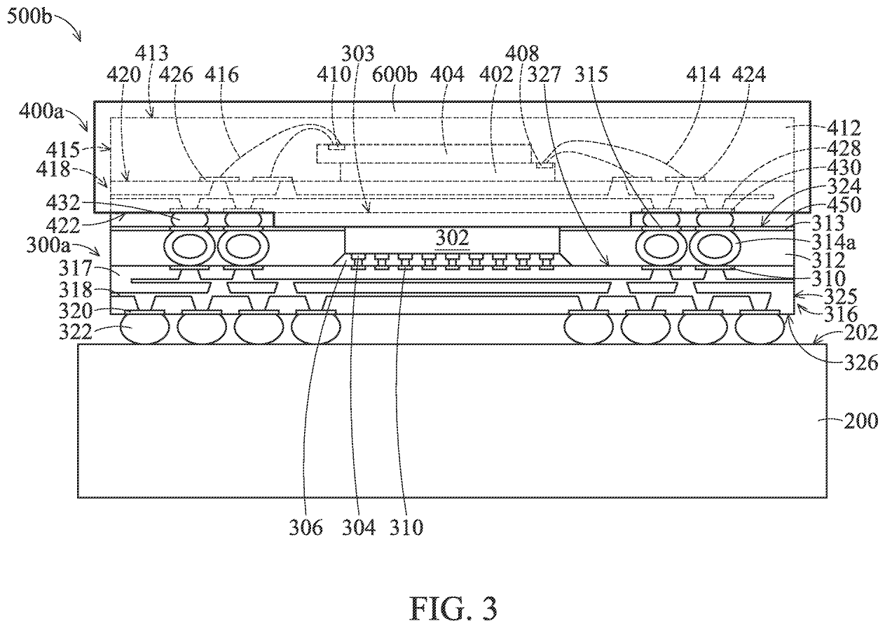

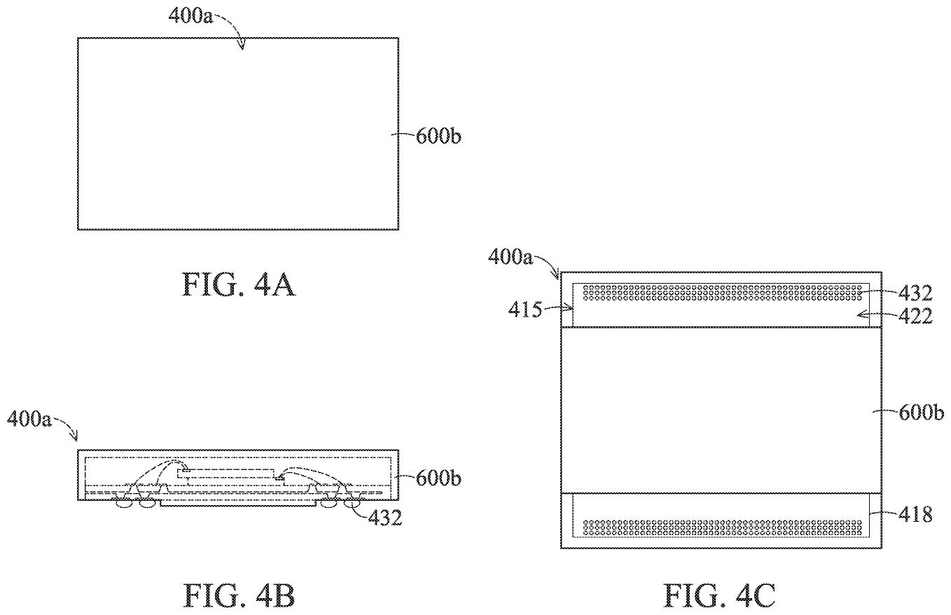

FIG. 3 is a cross-sectional of a semiconductor package assembly 500b in accordance with some embodiments of the disclosure. FIG. 4A is a top view showing the arrangements of a heat spreader 600b and the memory package 400a of the semiconductor package assembly 500b shown in FIG. 3 in accordance with some embodiments of the disclosure. FIG. 4B is a side view showing the arrangements of the heat spreader 600b and the memory package 400a of the semiconductor package assembly 500b shown in FIG. 3 in accordance with some embodiments of the disclosure. FIG. 4C is a bottom view showing the arrangements of the heat spreader 600b and the memory package 400a of the semiconductor package assembly 500b shown in FIG. 3 in accordance with some embodiments of the disclosure. Elements of the embodiments hereinafter, that are the same or similar as those previously described with reference to FIGS. 1 and 2A-2C, are not repeated for brevity.

The difference between the semiconductor package assembly 500a and the semiconductor package assembly 500b is that the semiconductor package assembly 500b comprises a heat spreader 600b wrapping around the memory package 400a and fully covers the top surface 413 and the side surfaces 415 of the memory package 400a. In some embodiments, the heat spreader 600b is formed by a coating process, such as a sputtering process. Therefore, the heat spreader 600b can be conformally formed covering the entire top surface 413 and the entire side surfaces 415 and a portion of the bottom surface 422 of the substrate 418. The heat spreader 600b is formed without covering the remaining portion of the bottom surface 422 of the substrate 418 close to and/or covered by the conductive structures 432, as shown in FIGS. 3 and 4A-4C. Therefore, the conductive structures 432 and/or the conductive structures 314a are separated from the heat spreader 600b to avoid a short between the conductive structures 432 and/or the conductive structures 314a and the heat spreader 600b. In addition, the heat spreader 600b can be formed in contact with the molding compound 412 and the substrate 418 of the memory package 400a. In some embodiments, the heat spreaders 600a and 600b may be formed of the same or similar materials. In some embodiments, the thickness of the heat spreader 600b may be thinner than that of the heat spreader 600a.

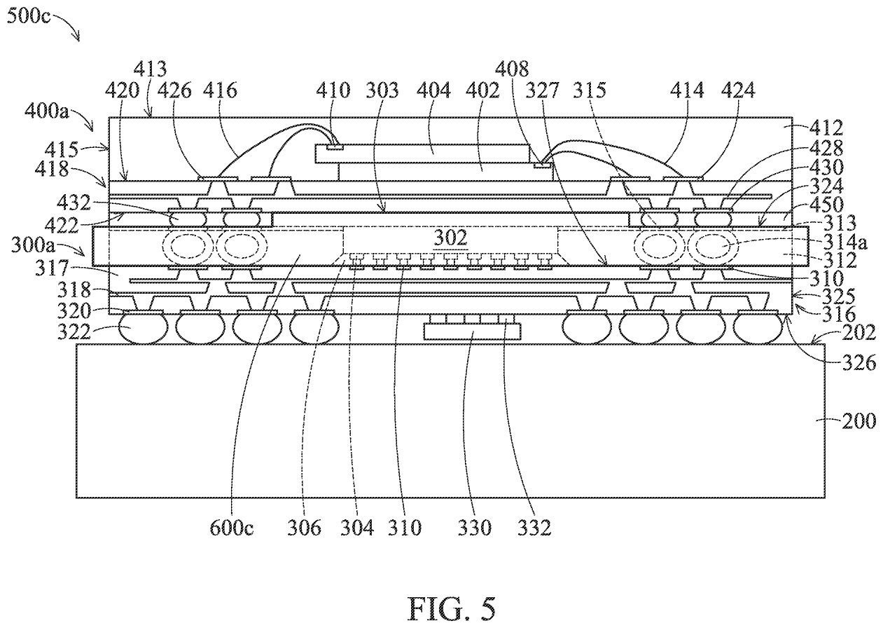

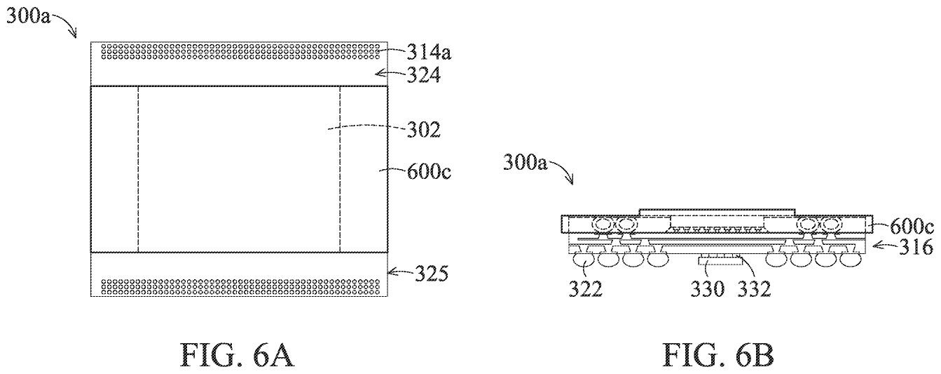

FIG. 5 is a cross-sectional of a semiconductor package assembly 500c in accordance with some embodiments of the disclosure. FIG. 6A is a top view showing the arrangements of a heat spreader 600c and the system-on-chip (SOC) package 300a of the semiconductor package assembly 500c shown in FIG. 5 in accordance with some embodiments of the disclosure. FIG. 6B is a side view showing the arrangements of the heat spreader 600c and the system-on-chip (SOC) package 300a of the semiconductor package assembly 500c shown in FIG. 5 in accordance with some embodiments of the disclosure. Elements of the embodiments hereinafter, that are the same or similar as those previously described with reference to FIGS. 1, 2A-2C, 3 and 4A-4C are not repeated for brevity.

The difference between the semiconductor package assembly 500a and the semiconductor package assembly 500c is that the semiconductor package assembly 500c comprises a heat spreader 600c wrapping around the SOC package 300a. In some embodiments, the heat spreader 600c is disposed between the underfill 450 and the back surface 303 of the logic die 302 of the SOC package 300a. In addition, the heat spreader 600c is wrapped around the side surfaces 325 of the SOC package 300a and partially covers the top surface 324 of the SOC package 300a.

In some embodiments, the heat spreader 600c is formed by a coating process, such as a sputtering process. Therefore, the heat spreader 600c can be conformally formed covering a portion of the top surface 324 and portions of the side surfaces 325 of the SOC package 300a. In some embodiments, the heat spreader 600c is formed without covering the remaining portion of the top surface 324 of the SOC package 300a overlapping the conductive structures 314a, as shown in FIGS. 5, 6A and 6B. The conductive structures 314a and/or the conductive structures 432 are separated from the heat spreader 600c to avoid a short between the conductive structures 314a and/or the conductive structures 432 and the heat spreader 600c. In addition, the heat spreader 600c can be formed in contact with the molding compound 312 of the SOC package 300a. Furthermore, the heat spreader 600c may be formed without covering side surfaces (a portion of the side surfaces 325) and the bottom surface 326 of the substrate 316 of the SOC package 300a because the heat generated form the logic die 302 mainly transmits to the upper the memory package 400a. In some embodiments, the heat spreaders 600a, 600b and 600c may be formed of the same or similar materials. In some embodiments, the thickness of the heat spreader 600c may be thinner than that of the heat spreader 600a, and the thickness of the heat spreader 600c may be the same as that of the heat spreader 600b.

In some embodiments, the semiconductor package assemblies 500a, 500b and 500c use the underfill 450 filled the gap between the upper memory package 400a and the lower SOC package 300a to reduce the thermal resistance from the SOC package 300a to the memory package 400a. In addition, the memory package 400a and the SOC package 300a may have suitable pin assignments close to edges of the packages. Therefore, the SOC package 300a can be fabricated without an interposer provided for the electrical connections between the SOC package 300a and the memory package 400a. Therefore, the height of the semiconductor package assemblies 500a, 500b and 500c can be further reduced. In some embodiments, the semiconductor package assemblies 500a, 500b and 500c further comprise the heat spreaders 600a, 600b and 600c disposed between the bottom surface 422 of the memory package 400a and the top surface 324 of the SOC package 300a. The heat spreaders 600a, 600b and 600c are in contact with the back surface 303 of the logic die 302, thereby providing an additional heat dissipating path that directly dissipates the heat from the SOC package 300a to the outside environment in addition to the original heat dissipating paths (e.g., the conductive paths from the lower SOC package 300a to the upper memory package 400a). Therefore, the heat dissipation capability of the semiconductor package assemblies 500a, 500b and 500c can be further improved.

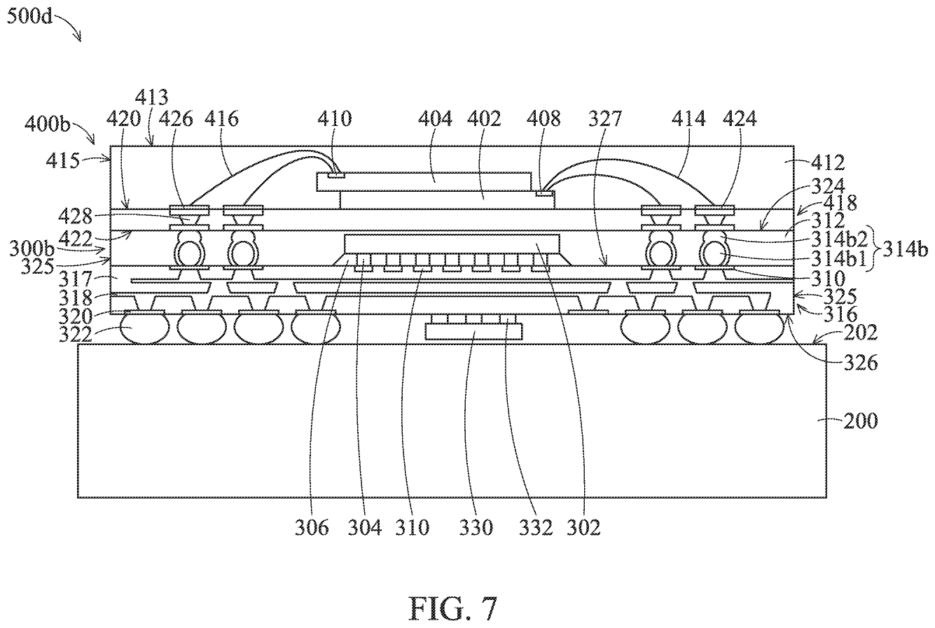

FIG. 7 is a cross-sectional of a semiconductor package assembly 500d in accordance with some embodiments of the disclosure. Elements of the embodiments hereinafter, that are the same or similar as those previously described with reference to FIGS. 1, 2A-2C, 3, 4A-4C, 5, 6A and 6B are not repeated for brevity.

In some embodiments, the semiconductor package assembly 500d is a three-dimensional (3D) package-in-package (PIP) semiconductor package assembly. The semiconductor package assembly 500b may include at least two vertically stacked wafer-level semiconductor packages mounted on the base 200. As shown in FIG. 7, in some embodiments, the semiconductor package assembly 500d includes a system-on-chip (SOC) package 300b, a memory package 400b vertically stacked on the SOC package 300b.

As shown in FIG. 7, the SOC package 300b is mounted on the die-attach surface 202 of the base 200 by a bonding process. One of the differences between the SOC package 300a and the SOC package 300b is that the SOC package 300b comprises conductive structures 314b disposed on the surface 327 of the substrate 316, wherein the logic die 302 is disposed on and electrically connected to the substrate 316. In some embodiments, the conductive structures 314b comprise a single structure or a composite structure. For example, the conductive structures 314b may comprise a single structure the same or similar as the conductive structures 314a. For example, the conductive structures 314b may comprise a composite structure including a conductive sub-structure 314b1 and a conductive sub-structure 314b2 connected to each other. In some embodiments, the conductive sub-structure 314b1 comprises the same or similar structure as the conductive structures 314a. In some embodiments, the conductive sub-structure 314b2 comprises a pre-solder structure.

Another difference between the SOC package 300a and the SOC package 300b is that the molding compound 312 of the SOC package 300b surrounding the logic die 302 is in contact with the back substrate 303 and the logic die 302. In addition, the molding compound 312 covers the entire back surface 303 of the logic die 302.

In some embodiments, the SOC package 300b is fabricated without the solder mask layer 313 and the pads 315 covering a top surface of the molding compound 312 opposite the substrate 316. Therefore, the top surface of the molding compound 312 may serve as the top surface 324 of the SOC package 300b. The conductive structures 314b pass through the molding compound 312 and are exposed from the top surface of the molding compound 312 away from the substrate 316 (i.e., the top surface 324 of the SOC package 300b).

As shown in FIG. 7, the memory package 400b is stacked on the SOC package 300b by a bonding process. One of the differences between the memory package 400a and the memory package 400b is that the memory package 400b is fabricated without the conductive structures 432 as shown in FIG. 1. In some embodiments, the memory package 400b is stacked on the SOC package 300b without there being a gap between them. In addition, the bottom surface 422 of the substrate 418 of the memory package 400b may be in contact with the top surface 324 of the SOC package 300b without there being a gap in between them. As shown in FIG. 7, the metal pads 430 close to the bottom surface 422 of the substrate 418 of the memory package 400b may be in contact with the corresponding conductive structure 314b of the SOC package 300b. In some embodiments, the molding compound 312 is in contact with the bottom surface 422 of the substrate 418 of the memory package 400b.

In some embodiments, the semiconductor package assembly 500d is designed to stack the memory package 400b on the SOC package 300b in a way that the bottom surface 422 of the substrate 418 of the memory package 400b is in contact with the conductive structure 314b of the SOC package 300b without there being a gap between them. Therefore, the thermal resistance from the SOC package 300b to the memory package 400b can be reduced. In addition, the heat dissipation capability of the semiconductor package assembly 500d can be further improved. Furthermore, the memory package 400b and the SOC package 300b may have suitable pin assignments close to edges of the packages. Therefore, the SOC package 300b can be fabricated without an interposer, the solder mask layer and the correspond pads close to the top surface 324 provided for the electrical connections between the SOC package 300b and the memory package 400b. In addition, the memory package 400b can be fabricated without the conductive structures (e.g. the conductive structures 432 shown in FIG. 1) between the bottom surface 422 of the memory package 400b and the top surface 324 of the SOC package 300b. Therefore, the height of the semiconductor package assembly 500d can be further reduced.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a system-on-chip (SOC) package, comprising:
a logic die having pads; and
a first substrate electrically connected to the logic die by the pads;
a memory package stacked on the SOC package, comprising:
a second substrate having a top surface and a bottom surface; and
a memory die mounted on the top surface of the second substrate and
electrically connected to the second substrate using bonding wires; and
a heat spreader between the SOC package and the memory package, wherein the heat spreader is in contact with a back surface of the logic die away from the pads.

2. The semiconductor package assembly as claimed in claim 1, further comprising:
an underfill filling a gap between the SOC package and the memory package,
wherein the underfill is in contact with the heat spreader.

3. The semiconductor package assembly as claimed in claim 2, wherein the heat spreader is between the underfill and the back surface of the logic die.

4. The semiconductor package assembly as claimed in claim 1, wherein the heat spreader partially overlaps the bottom surface of the second substrate.

5. The semiconductor package assembly as claimed in claim 4, wherein the heat spreader covers the entire memory die.

6. The semiconductor package assembly as claimed in claim 4, wherein the heat spreader is wrapped around the memory package and partially covers a top surface and side surfaces of the memory package.

7. The semiconductor package assembly as claimed in claim 4, wherein the heat spreader is wrapped around the memory package and fully covers the top surface and side surfaces of the memory package.

8. The semiconductor package assembly as claimed in claim 4, wherein the heat spreader is wrapped around side surfaces of the SOC package and partially covers a top surface of the SOC package.

9. The semiconductor package assembly as claimed in claim 1, wherein the SOC package comprises:
a molding compound surrounding the logic die, being in contact with the first substrate and the logic die; and
first conductive structures passing through the molding compound and electrically connected to the memory package, wherein the first conductive structures of the SOC package are separated from the heat spreader.

10. The semiconductor package assembly as claimed in claim 9, wherein the memory package comprises:
second conductive structures disposed on the bottom surface of the second substrate and electrically connected to the first conductive structures of the SOC package, wherein the conductive structures of the memory package are separated from the heat spreader.

11. The semiconductor package assembly as claimed in claim 10, wherein the second conductive structures are surrounded by an underfill between the SOC package and the memory package.

12. The semiconductor package assembly as claimed in claim 1, wherein the heat spreader comprises a conductive material.

13. The semiconductor package assembly as claimed in claim 1, further comprising:
an adhesive between the heat spreader and the memory package.

14. A semiconductor package assembly, comprising:
a system-on-chip (SOC) package, comprising:
a logic die, wherein a back surface of the logic die is exposed from a top surface of the SOC package; and
a first substrate electrically connected to the logic die;
a memory package stacked on the SOC package, comprising:
a second substrate having a top surface and a bottom surface; and
a memory die mounted on the top surface of the second substrate and
electrically connected to the second substrate using bonding wires; and
a heat spreader partially overlapping the bottom surface of the second substrate,
being in contact with the back surface of the logic die.

15. The semiconductor package assembly as claimed in claim 14, wherein the heat spreader is disposed between the SOC package and the memory package.

16. The semiconductor package assembly as claimed in claim 14, wherein the heat spreader fully covers the back surface of the logic die.

17. The semiconductor package assembly as claimed in claim 14, wherein the heat spreader is wrapped around the SOC package or the memory package.

18. The semiconductor package assembly as claimed in claim 17, wherein the heat spreader is wrapped around the memory package and covers portions of a top surface and side surfaces of the memory package.

19. The semiconductor package assembly as claimed in claim 17, wherein the heat spreader is wrapped around the memory package and fully covers a top surface and side surfaces of the memory package.

20. The semiconductor package assembly as claimed in claim 17, wherein the heat spreader is wrapped around side surfaces of the SOC package and partially covers a top surface of the SOC package.

21. The semiconductor package assembly as claimed in claim 14, further comprising:
an underfill filling a gap between the SOC package and the memory package,
wherein the heat spreader is adjacent to the underfill.

22. The semiconductor package assembly as claimed in claim 21, wherein the heat spreader is between the underfill and the back surface of the logic die.

23. The semiconductor package assembly as claimed in claim 21, wherein the SOC package comprises:
a molding compound surrounding the logic die, being in contact with the first substrate and the logic die; and
first conductive structures passing through the molding compound and electrically connected to the memory package, wherein the first conductive structures of the SOC package are separated from the heat spreader.

24. The semiconductor package assembly as claimed in claim 23, wherein the memory package comprises:
second conductive structures disposed on the bottom surface of the second substrate, surrounded by an underfill and electrically connected to the first conductive structures of the SOC package, wherein the second conductive structures are separated from the heat spreader.

25. A semiconductor package assembly, comprising:
a system-on-chip (SOC) package, comprising:
a logic die; and
a first substrate electrically connected to the logic die;
a memory package stacked on the SOC package without a gap therebetween, comprising:
a second substrate having a top surface and a bottom surface; and
a memory die mounted on the top surface of the second substrate and
electrically connected to the second substrate using bonding wires; and
a heat spreader between the SOC package and the memory package, being in contact with the logic die.

26. The semiconductor package assembly as claimed in claim 25, wherein the logic die has pads, wherein the heat spreader is in contact with a back surface of the logic die away from the pads.

27. The semiconductor package assembly as claimed in claim 25, wherein a back surface of the logic die is aligned with a top surface of the SOC package, wherein the heat spreader is in contact with the back surface of the logic die.

28. The semiconductor package assembly as claimed in claim 25, wherein the heat spreader is wrapped around the memory package and covers portions of a top surface and side surfaces of the memory package.

29. The semiconductor package assembly as claimed in claim 25, wherein the heat spreader is wrapped around the memory package and fully covers a top surface and side surfaces of the memory package.

30. The semiconductor package assembly as claimed in claim 25, wherein the heat spreader is wrapped around side surfaces of the SOC package and partially covers a top surface of the SOC package.

31. The semiconductor package assembly as claimed in claim 25, further comprising:
an underfill filling a gap between the SOC package and the memory package,
wherein the heat spreader is in contact with the underfill and the back surface of the logic die.

32. The semiconductor package assembly as claimed in claim 31, wherein the heat spreader is between the underfill and the back surface of the logic die.

33. The semiconductor package assembly as claimed in claim 25, wherein the SOC package comprises:
a molding compound surrounding the logic die, being in contact with the first substrate and the logic die; and
first conductive structures passing through the molding compound and electrically connected to the memory package, wherein the first conductive structures of the SOC package are separated from the heat spreader.

34. The semiconductor package assembly as claimed in claim 33, wherein the memory package comprises:
second conductive structures disposed on the bottom surface of the second substrate, surrounded by an underfill and electrically connected to the first conductive structures of the SOC package, wherein the second conductive structures are separated from the heat spreader.
